(19) United States
(12) Patent Application Publication
(10) Pub. No.: US 2023/0240158 A1
(43) Pub. Date: Jul. 27, 2023

(54) SEMICONDUCTOR MEMORY DEVICE

(71) Applicant: SK hynix Inc., Icheon-si (KR)

(72) Inventor: Gwang Hyuk SHIN, Icheon-si (KR)

(21) Appl. No.: 17/942,814

(22) Filed: Sep. 12, 2022

(30) Foreign Application Priority Data
Jan. 26, 2022 (KR) 10-2022-0011531

(51) Int. Cl. H01L 45/00; H01L 27/24; H01L 23/528

(52) U.S. Cl. CPC H01L 45/06; H01L 27/2481; H01L 45/1253; H01L 23/5283

(57) ABSTRACT

A semiconductor memory device may include one or more memory cells, and each of the memory cells may include a memory unit for storing data; and a selection element unit electrically connected to the memory unit and including a first electrode layer, a second electrode layer, and a selection element layer that includes an insulating material layer doped with a dopant and is interposed between the first electrode layer and the second electrode layer, wherein the insulating material layer has a two-dimensional crystalline structure.

### PRIORITY CLAIM AND CROSS-REFERENCE TO RELATED APPLICATION

This patent document claims the priority and benefits of Korean Patent Application No. 10-2022-0011531 filed on Jan. 26, 2022, which is incorporated herein by reference in its entirety.

### TECHNICAL FIELD

This patent document relates to memory circuits or devices and their applications in electronic devices or systems.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include semiconductor devices such as memory devices that can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an electronic fuse (E-fuse).

### SUMMARY

The disclosed technology can be implemented in some embodiments to provide a semiconductor memory device including memory cells that can improve the reliability of the semiconductor memory device by improving the reliability of selection element layers in the memory cells.

In an embodiment, a semiconductor memory device may include one or more memory cells, and each of the memory cells may include a memory unit for storing data; and a selection element unit electrically connected to the memory unit and including a first electrode layer, a second electrode layer, and a selection element layer that includes an insulating material layer doped with a dopant and is interposed between the first electrode layer and the second electrode layer, wherein the insulating material layer has a two-dimensional crystalline structure.

In another embodiment, a semiconductor memory device comprising one or more memory cells, wherein each of the memory cells is structured to store data and includes a first electrode disposed on a substrate, a selector including a two-dimensional crystalline insulating material layer doped with a dopant structure and formed on the first electrode to exhibit different electrically conductive states depending on whether a voltage applied thereto is above or below a threshold voltage to select or de-select the memory cell for a memory operation, and a second electrode disposed on the selector so that the first and second electrodes are connected to apply the voltage to the selector.

### BRIEF DESCRIPTION OF THE DRAWINGS

FIG. 1 is a perspective view illustrating a memory device based on some embodiments of the disclosed technology.

FIG. 2 is a cross-sectional view illustrating a selection element unit based on some embodiments of the disclosed technology.

FIG. 3 is an energy band diagram illustrating the operation of the selection element unit of FIG. 2.

FIG. 4 is a graph showing threshold voltage characteristics of a selection element layer implemented based on some embodiments of the disclosed technology and another example selection element layer.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers).

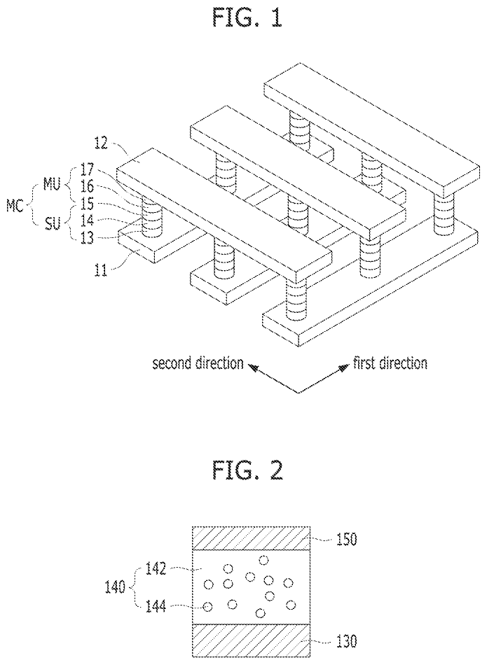

FIG. 1 is a perspective view illustrating a memory device based on some embodiments of the disclosed technology.

Referring to FIG. 1, the memory device based on some embodiments of the disclosed technology may include a plurality of lower conductive interconnect structures 11 extending in a first direction. In some implementations, the lower conductive interconnect structures 11 are arranged in parallel with each other. In addition, the memory device based on some embodiments of the disclosed technology may include a plurality of upper conductive interconnect structures 12 extending in a second direction crossing the first direction. In some implementations, the upper conductive interconnect structures 12 are arranged in parallel with each other while being disposed over the plurality of lower conductive interconnect structures 11. The memory device based on some embodiments of the disclosed technology may also include memory cells MC interposed between the lower conductive interconnect structures 11 and the upper conductive interconnect structures 12 at intersections of the lower conductive interconnect structures 11 and the upper conductive interconnect structures 12, respectively.

The memory cell MC may include a memory unit MU and a selection element unit SU. In some implementations, the memory unit MU is structured to store data, and the selection element unit SU is used to control access to the memory unit MU. As an example, the memory cell MC may include a stacked structure that includes a lower electrode layer 13, a selection element layer 14 disposed over the lower electrode layer 13, an intermediate electrode layer 15 disposed over the selection element layer 14, a variable resistance layer 16 disposed over the intermediate electrode layer 15, and an upper electrode layer 17 disposed over the variable resistance layer 16. In some implementations, the lower electrode layer 13, the selection element layer 14, and the intermediate electrode layer 15 constitute the selection element unit SU, and the intermediate electrode layer 15, the variable resistance layer 16, and the upper electrode layer 17 constitute the memory unit MU. The intermediate electrode layer 15 may be shared by the selection element unit SU and the memory unit MU.

The lower electrode layer 13 and the upper electrode layer 17 may be located at both ends, for example, at the bottom and top ends of the memory cell MC, respectively, and may function to transmit a voltage or current required for read/write operations of the memory cell MC. The intermediate electrode layer 15 may function to electrically connect the selection element layer 14 to the variable resistance layer 16 while physically isolating them from each other. The lower electrode layer 13, the intermediate electrode layer 15, or the upper electrode layer 17 may be formed of various conductive materials, for example, a metal such as platinum (Pt), tungsten (W), aluminum (Al), copper (Cu), tantalum (Ta), or titanium (Ti), a metal nitride such as titanium nitride (TiN) or tantalum nitride (TaN), or a combination thereof. Alternatively, the lower electrode layer 13, the intermediate electrode layer 15, or the upper electrode layer 17 may include a carbon electrode.

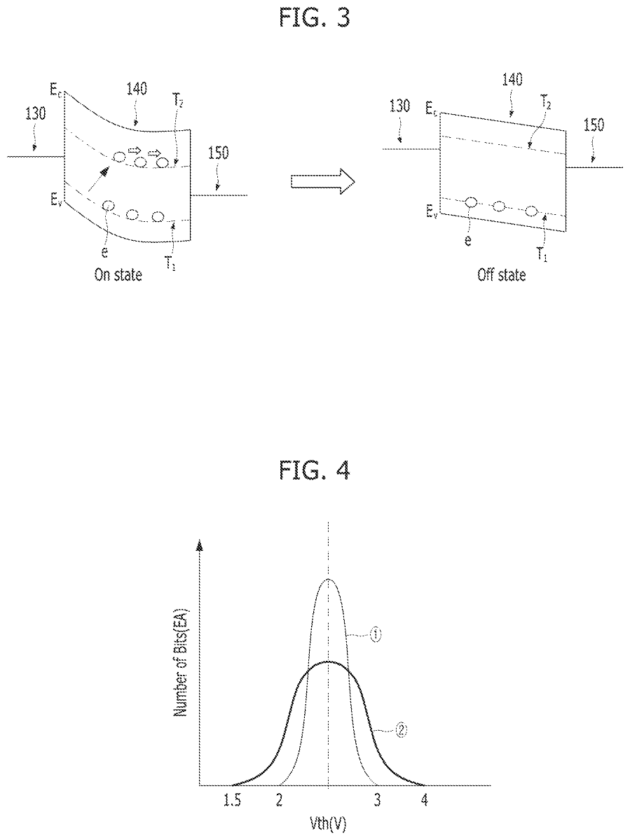

The selection element layer 14 may function to prevent current leakage that may occur between the memory cells MC sharing the lower conductive interconnect structure 11 or the upper conductive interconnect structure 12. To this end, the selection element layer 14 may perform a threshold switching. For example, the threshold switching indicates that no or very small amount of current flows when a magnitude of an applied voltage is less than a predetermined threshold value, and the current abruptly increases above the threshold value when the applied voltage reaches or is higher than the predetermined threshold value. Here, the threshold value may be referred to as a threshold voltage. In some embodiments, the selection element layer 14 may include a two-dimensional crystalline insulating material that is doped with a dopant. The selection element layer 14 may include electrode layers and a selection element layer between the electrode layers as will be discussed below with reference to FIGS. 2 and 3.

The variable resistance layer 16 may be used to store data in the memory cell MC. To this end, the variable resistance layer 16 may have a variable resistance that switches between different resistance states according to an applied voltage. The variable resistance layer 16 may have a single-layered structure or a multi-layered structure. The variable resistance layer 16 may be formed of materials that can be used form a memory cell structure of an RRAM, a PRAM, an MRAM, or an FRAM. For example, the variable resistance layer 16 may include a metal oxide such as a perovskite-based oxide or a transition metal oxide, a phase change material such as a chalcogenide-based material, a ferromagnetic material, a ferroelectric material, or others.

FIG. 1 illustrates the layers in the memory cell MC are: the lower electrode layer 13, the selection element layer 14 disposed over the lower electrode layer 13, the intermediate electrode layer 15 disposed over the selection element layer 14, the variable resistance layer 16 disposed over the intermediate electrode layer 15, and the upper electrode layer 17 disposed over the variable resistance layer 16. However, in other implementations, the layers in in the memory cell MC can be stacked in a different order and/or at least one of the layers illustrated in FIG. 1 may be omitted. As an example, one or more lower electrode layers 13, the intermediate electrode layer 15, and the upper electrode layer 17 may be omitted. As another example, the memory cell MC may include a lower electrode layer 13, a variable resistance layer 16 disposed over the lower electrode layer 13, an intermediate electrode layer 15 disposed over the variable resistance layer 16, a selection element layer 14 disposed over the intermediate electrode layer 15, and an upper electrode layer 17 disposed over the selection element layer 14. In some implementations, one or more additional layers (not shown) may be added to the memory cell MC.

The memory cell MC described above may have a pillar shape to be separated from the adjacent memory cell MC. In some embodiments of the disclosed technology, the memory cell MC may have a cylindrical shape. In another embodiment, the memory cell MC may have a quadrangular pillar shape having both sides aligned with both sides of the upper conductive interconnect structure 12 in the first direction and both sides aligned with both sides of the lower conductive interconnect structure 11 in the second direction. In addition, in some embodiments of the disclosed technology, the selection element layer 14 and the variable resistance layer 16 may be patterned at once, that is, using a single mask, so the side surfaces thereof may be aligned with each other. In some implementations, the selection element layer 14 and the variable resistance layer 16 may be separately patterned, and thus may have side surfaces that are not aligned with each other.

FIG. 2 is a cross-sectional view illustrating a selection element unit based on some embodiments of the disclosed technology, and FIG. 3 is an energy band diagram illustrating the operation of the selection element unit of FIG. 2.

Referring to FIG. 2, the selection element unit implemented based on some embodiments of the disclosed technology may include a first electrode layer 130, a second electrode layer 150, and a selection element layer 140 between the first electrode layer 130 and the second electrode layer 150. The first electrode layer 130, the second electrode layer 150, and the selection element layer 140 may correspond to the lower electrode layer 13, the intermediate electrode layer 15, and the selection element layer 14 illustrated in FIG. 1, respectively.

The selection element layer 140 may include an insulating material layer 142 and a dopant 144 doped in the insulating material layer 142.

The insulating material layer 142 may include a two-dimensional crystalline insulating material. In some implementations, the material that constitutes the insulating material layer 142 may have covalent bonds in a horizontal direction and van der Waals bonds in a vertical direction, and thus the insulating material layer 142 may have a structure in which crystalline atomic-level thin films are stacked on top of one another in the vertical direction. In addition, the insulating material layer 142 may include an insulating material having a relatively wide band gap, for example, a band gap of 5 to 6 eV. As an example, the insulating material layer 142 may include hexagonal boron nitride (h-BN). In some implementations, an inherent deep trap may exist in the insulating material layer 142.

The dopant 144 may include an immobile dopant retained in the insulating material layer 142 that creates a shallow trap to provide a passageway for conductive carriers in the insulating material layer 142. In some implementations, the shallow trap may have an energy level that is greater than a work function of at least one of the first and second electrode layers 130 and 150 and less than an energy level of a conduction band of the insulating material layer 142. To form such a shallow trap, various elements may be used as the dopant 144 so long as they can generate an energy level accommodating conductive carriers in the insulating material layer 142. The dopant 144 may include an element that has a valence different from a valence of at least one of elements that constitute the insulating material layer 142. For example, the dopant 144 may include gallium (Ga), indium (In), phosphorus (P), arsenic (As), antimony (Sb), germanium (Ge), silicon (Si), carbon (C), tungsten (W), or a combination thereof.

As an example, the selection element layer 140 may include hexagonal boron nitride doped with arsenic (As).

In some implementations, the selection element unit discussed in this patent document can be operated as will be discussed below with reference to FIG. 3.

In some implementations, in a state where no voltage is applied to the selection element layer 140, conductive carriers such as electrons may be trapped in a deep trap T1 of the selection element layer 140. The energy level of the deep trap T1 may be similar to an energy level Ev of a valence band of the insulating material layer 142 forming the selection element layer 140.

When a voltage equal to or greater than a threshold voltage is applied to the selection element layer 140 in this state through the first and second electrode layers 130 and 150, the selection element layer 140 may be turned on (See “On state” in FIG. 3), thus providing an electrical pathway to the corresponding memory unit MU that is connected in series with the selection element unit. More specifically, when the voltage greater than or equal to the threshold voltage is applied to the selection element layer 140, the conductive carriers of the deep trap T1 may jump to a shallow trap T2 by thermal emission or tunneling, and a conductive path connecting the first electrode layer 130 to the second electrode layer 150 may be created by the conductive carriers that move through the shallow trap T2.

If the voltage applied to the selection element layer 140 in the on-state is reduced, the selection element layer 140 may be turned off at a certain point (See “Off state” in FIG. 3). When the voltage applied to the selection element layer 140 is reduced, the number of conductive carriers moving from the deep trap T1 to the shallow trap T2 may be gradually reduced, and thus the conductive path connecting the first electrode layer 130 and the second electrode layer 150 may be cut off, thus preventing an electrical pathway to the memory unit MU that is connected in series with the selection element unit.

In such on/off operations by the selection element unit, the selection element unit effectuates a selection mechanism for selecting its corresponding memory unit MU to be connected with the memory circuit (when the selection element is in the on state to be electrically conductive) or de-selecting the corresponding memory unit MU to be disconnected from the memory circuit (when the selection element is in the off state to be electrically non-conductive). The selection element layer 140 implemented based on some embodiments of the disclosed technology may have the following advantages over other selection element layers such as a selection element layer that includes an amorphous insulating material layer doped with a dopant, for example, amorphous silicon dioxide (SiO₂) doped with arsenic (As).

In such a selection element layer made of an amorphous insulating material layer doped with a dopant, the amorphous insulating material layer may have many randomly distributed dangling bonds. For example, the dangling bond density in the amorphous insulating material layer may have a value in the range of about 10¹⁹ to 10²⁰/cnn³. In this case, during on/off operations of the selection element layer, conductive carriers may be trapped or de-trapped by the dangling bonds, and thus random telegraph noise may be generated. Accordingly, the reliability of the selection element layer may be deteriorated, resulting in unstable threshold voltage characteristics of the selection element layer.

On the other hand, in some embodiments of the disclosed technology, the two-dimensional crystalline insulating material layer 142 contained in the selection element layer 140 may have no or very few dangling bonds, or may have dangling bonds having a lower density than that of the amorphous insulating material layer. For example, the dangling bond density of the two-dimensional crystalline insulating material layer 142 may have a value of less than about 10¹⁹/cm3. Accordingly, during the on/off operations of the selection element layer 140, trapping and de-trapping of the conductive carriers due to the dangling bonds may be reduced, and thus the reliability of the selection element layer 140 may be improved.

In some implementations, the selection element layer 140 may be formed by: performing a deposition method such as CVD (Chemical Vapor Deposition), forming the insulating material layer 142; and performing an ion implantation of the dopant 144 into the insulating material layer 142. During the ion implantation, dangling bonds may be formed in the insulating material layer 142 due to the damage to the insulating material layer 142 caused by the ion implantation. In order to reduce or minimize such dangling bonds, the acceleration voltage and the dose amount of the ion implantation may be lowered to below a predetermined threshold value.

FIG. 4 is a graph showing threshold voltage characteristics of a selection element layer implemented based on some embodiments of the disclosed technology and another example selection element layer. FIG. 4 shows a selection element layer (curve \textcircled{1}) based on some embodiments of the disclosed technology that includes hexagonal boron nitride doped with a dopant, and another example selection element layer (curve \textcircled{2}) that includes an amorphous silicon dioxide (SiO₂) doped with arsenic (As).

Referring to FIG. 4, the threshold voltage distribution of the selection element layer based on some embodiments of the disclosed technology (see curve \textcircled{1}) is smaller than that of another example selection element layer (see curve \textcircled{2}). This may be because the number of dangling bonds in the hexagonal boron nitride is smaller than the number of dangling bonds in the amorphous silicon dioxide (SiO₂). Therefore, in some embodiments, the trap/detrap of the conductive carrier due to the dangling bonds may be reduced.

As such, when the threshold voltage distribution is reduced, the controllable range of the threshold voltage may be increased, so that the degree of freedom in designing the semiconductor device may increase.

In some embodiments of the disclosed technology, it may be possible to provide a semiconductor memory device including memory cells that can improve the reliability of the semiconductor memory device by improving the reliability of selection element layers in the memory cells.

Although various embodiments have been described for illustrative purposes, it will be apparent to those skilled in the art that various changes and modifications may be made without departing from the spirit and scope of the present teachings as defined in the following claims.

What is claimed is:

1. A semiconductor memory device comprising one or more memory cells, each of the memory cells comprising:
a memory unit for storing data; and
a selection element unit electrically connected to the memory unit and including a first electrode layer, a second electrode layer, and a selection element layer that includes an insulating material layer doped with a dopant and is interposed between the first electrode layer and the second electrode layer, wherein the insulating material layer has a two-dimensional crystalline structure.

2. The semiconductor memory device according to claim 1, wherein the insulating material layer includes hexagonal boron nitride.

3. The semiconductor memory device according to claim 1, wherein the insulating material layer includes a shallow trap created by the dopant and providing a passageway for conductive carriers.

4. The semiconductor memory device according to claim 3, wherein the shallow trap has an energy level that is greater than a work function of at least one of the first electrode layer and the second electrode layer.

5. The semiconductor memory device according to claim 1, wherein the insulating material layer in the selection element layer includes dangling bonds, wherein a density of the dangling bonds of the insulating material layer is smaller than a density of dangling bonds of an amorphous insulating material.

6. The semiconductor memory device according to claim 1, wherein the dopant includes an element that has a valence different from a valence of at least one of elements that constitute the insulating material layer.

7. The semiconductor memory device according to claim 1, wherein the dopant includes gallium (Ga), indium (In), phosphorus (P), arsenic (As), antimony (Sb), germanium (Ge), silicon (Si), carbon (C), tungsten (W), or a combination thereof.

8. The semiconductor memory device according to claim 1, further comprising:
a plurality of lower conductive interconnect structures extending in a first direction; and
a plurality of upper conductive interconnect structures extending in a second direction intersecting the first direction,
wherein the memory cell is interposed between the lower conductive interconnect structures and the upper conductive interconnect structures at each intersection of the lower conductive interconnect structures and the upper conductive interconnect structures.

9. A semiconductor memory device comprising one or more memory cells, wherein each of the memory cells is structured to store data and includes:
a first electrode disposed on a substrate;
a selector including a two-dimensional crystalline insulating material layer doped with a dopant structure and formed on the first electrode to exhibit different electrically conductive states depending on whether a voltage applied thereto is above or below a threshold voltage to select or de-select the memory cell for a memory operation; and
a second electrode disposed on the selector so that the first and second electrodes are connected to apply the voltage to the selector.

10. The semiconductor memory device according to claim 9, wherein the insulating material layer includes hexagonal boron nitride.

11. The semiconductor memory device according to claim 9, wherein the insulating material layer includes a shallow trap created by the dopant and providing a passageway for conductive carriers.

12. The semiconductor memory device according to claim 11, wherein the shallow trap has an energy level that is greater than a work function of at least one of the first electrode layer and the second electrode layer.

13. The semiconductor memory device according to claim 9, wherein the dopant includes gallium (Ga), indium (In), phosphorus (P), arsenic (As), antimony (Sb), germanium (Ge), silicon (Si), carbon (C), tungsten (W), or a combination thereof.

14. The semiconductor memory device according to claim 9, wherein each memory cell includes a variable resistance material that stores data by changing a resistance of the variable resistance material.

15. The semiconductor memory device according to claim 9, wherein each memory cell includes a phase change material that stores data by changing a state of the phase change material between amorphous and crystalline states.

16. The semiconductor memory device according to claim 9, wherein each memory cell includes a magnetic material that stores data by changing a magnetic direction of the magnetic material.
